(19) United States
(12) Patent Application Publication
(10) Pub. No.: US 2006/0047451 A1
(43) Pub. Date: Mar. 2, 2006

(54) Apparatus and method for circuit diagram display, and computer product

(75) Inventors: Mituru Sato, Kawasaki (JP); Yuki Kumon, Kawasaki (JP); Hiroji Takeyama, Kawasaki (JP); Terunobu Maruyama, Isahaya (JP); Miki Takagi, Kawasaki (JP); Tomoki Kanemochi, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/022,969

(22) Filed: Dec. 28, 2004

(30) Foreign Application Priority Data
Sep. 2, 2004 (JP) 2004-256260

(51) Int. Cl. G01R 13/00

(52) U.S. Cl. 702/71

(57) ABSTRACT

A circuit diagram display apparatus displays a plurality of logic circuit diagrams. An associating unit associates the logic circuits based on at least any one of identification information, structural information, logical equivalence information, and external designated information about the logic circuits. A display format changing unit changes a display format between a side-by-side format and one-below-the-other format. A display controller performs control to display a target point in the logic circuit diagram in the same position before and after the display format is changed.

### BACKGROUND OF THE INVENTION

1) Field of the Invention

The present invention relates to an apparatus and a method for circuit diagram display and a computer product that display on the same display screen, circuit areas which include a plurality of circuit diagrams or a part thereof, where the circuit areas are arranged in a certain order.

2) Description of the Related Art

In conventional logical equivalence verification techniques, when mismatching logic is detected, two circuit diagrams that are subjected to comparison are displayed on a display screen, and a designer analyzes a cause for the mismatching of logic while referring to these circuit diagrams. Concretely, when a part of a circuit structure is modified, circuit diagrams before and after the modifications are displayed side by side on the same display screen. Circuit areas with different logic are traced while referring to the display screen, and a difference in the structure of the circuit, which causes the mismatching, is searched.

To analyze the mismatching efficiently, a logical equivalence verification apparatus has been disclosed in Japanese Patent Application Laid-open Publication No. 2004-21944. In the logical equivalence verification apparatus, a logic cone that includes all inputs and all logic circuit elements, which affect one output of a combinational logic circuit that is selected for each of two logic circuits, is converted to a logical expression. The logical expression that is converted and the logic circuit element that is included in the logic cone are stored in correlation with each other. A logic circuit element that corresponds to an item designated in the logical expression converted is specified. By using the technology disclosed in Japanese Patent Application Laid-open Publication No. 2004-21944, a logic circuit element that causes the mismatching of the logic can be specified.

However, while analyzing the mismatching, it is necessary to display two circuit diagrams side by side to see the difference in the circuit before modification and the circuit after modification. According to the conventional technology, a format for displaying the two circuit diagrams side by side is fixed to a format in which the circuit diagrams are displayed one below the other, or a format in which the circuit diagrams are displayed side by side. The only way to change the format of the fixed display from the one below the other format to the side by side format, is opening the two circuit diagrams to be compared in two separate windows and arranging them manually. Moreover, because the formats that display the circuit diagrams side by side are fixed, a display range is narrow as compared to a range to be debugged and a shape of the circuit diagram, and a screen scrolling needs to be performed frequently.

When there is a mismatching, the designer tries to specify the location of cause of the mismatching by using information such as name of a module, name of an instance, as a clue. However, in a case of a large-scale circuit, the number of instances being enormous, a massive amount of labor work is required.

Further, when there is a mismatching, the designer goes on omitting checking the similar parts of a circuit structure to thereby narrow the checking range, and specifies the location of the mismatching. However, in the case of the large-scale circuit, due to the number of instances becoming enormous, the narrowing of the checking range becomes time-consuming, and a situation may arise where the checking range cannot be narrowed.

When there is a mismatching of logic in two circuits with similar circuit structures, the designer tries to specify the location of mismatching by visual observation. However, it is difficult to specify the cause of mismatching in two circuits with totally different circuit structures, and an efficiency of debugging is poor.

When there is a mismatching of logic in a repeat design or a split design, the designer excludes points that are already judged as verified and equivalent, and checks for the cause of the mismatching other than the locations excluded. However, because the exclusion of the locations, which are considered to be irrelevant to the mismatching, can be judged by visual observation, there is a possibility that the locations of mismatching may escape unnoticed, or may be viewed as matching locations, by mistake.

When the display of the two circuits that are displayed side by side is controlled by commands (such as scroll bar, screen fit, zoom in, and zoom out), the designer has to repeat the same operation for the two circuit diagrams, thereby affecting the efficiency of debugging.

Thus, to display a plurality of circuit diagrams side by side, it is very important that the two circuit diagrams be displayed side by side efficiently according to their features, that the corresponding locations of the circuit be apparent, and that the designer's labor be reduced. These issues can be derived for analog circuits in a manner similar to that for the logic circuits.

### SUMMARY OF THE INVENTION

It is an object of the present invention to at least solve the problems in the conventional technology.

A circuit diagram display apparatus according to an aspect of the present invention displays circuit areas side by side on a display screen, wherein the circuit area includes any one of a part and a whole of a plurality of circuit diagrams. The circuit diagram display apparatus includes a display format changing unit that changes a display format in any one way of from a one-below-the-other format to a side-by-side format, and from the side-by-side format to the one-below-the-other format by executing a command once, when the circuit area of the circuit diagram on the display screen is displayed in any one of the one-below-the-other format and the side-by-side format; and a display controller that performs a display control to display a target point in the circuit area, in the same position before and after the change in the display format, while the display format changing unit changes the display format on the display screen.

A circuit diagram display apparatus according to another aspect of the present invention displays circuit areas side by side on a display screen, wherein the circuit area includes any one of a part and a whole of a plurality of circuit diagrams. The circuit diagram display apparatus includes an associating unit that associates any one of a part of a circuit and an element that appears in various circuit areas in the plurality of the circuit diagrams; a gang controller that performs gang control of any one of a part of a circuit and an element included in a second circuit area associated with any one of a part of a circuit and an element of a predetermined circuit area from among the plurality of circuit areas, while any one of the part of the circuit and the element included in the predetermined circuit area is being operated.

A method according to still another aspect of the present invention is a method for displaying circuit areas side by side on a display screen, wherein the circuit area includes any one of a part and a whole of a plurality of circuit diagrams. The method includes changing a display format in any one way of from a one-below-the-other format to a side-by-side format, and from the side-by-side format to the one-below-the-other format by executing a command once, when the circuit area of the circuit diagram on the display screen is displayed in any one of the one-below-the-other format and the side-by-side format; and performing a display control to display a target point in the circuit area, in the same position before and after the change in the display format, while the display format on the display screen is being changed.

A method according to still another aspect of the present invention is a method for displaying circuit areas side by side on a display screen, wherein the circuit area includes any one of a part and a whole of a plurality of circuit diagrams. The method includes associating any one of a part of a circuit and an element that appears in various circuit areas in the plurality of the circuit diagrams; performing gang control of any one of a part of a circuit and an element included in a second circuit area associated with any one of a part of a circuit and an element of a predetermined circuit area from among the plurality of circuit areas, while any one of the part of the circuit and the element included in the predetermined circuit area is being operated.

The other objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a functional block diagram of a circuit diagram display apparatus according to a first embodiment;

FIG. 2A is an example of identification information of modules stored in a Spec identification information storage and an Impl identification information storage shown in FIG. 1;

FIG. 2B is an example of identification information of ports stored in the Spec identification information storage and the Impl identification information storage;

FIG. 3 is an example of a side by side display of circuit diagrams displayed by a side by side display section shown in FIG. 1;

FIG. 4 is an example of associated Spec logic circuit and Impl logic circuit, displayed by the circuit diagram display apparatus;

FIG. 5 is an example of an image display where the Spec logic circuit and the Impl logic circuit are converted from a world coordinate system to a screen coordinate system by a display controller shown in FIG. 1;

FIG. 6 is an example of an image display of the Spec logic circuit and the Impl logic circuit arranged one below the other by the display controller;

FIG. 7 is an example of an image display of the Spec logic circuit and the Impl logic circuit arranged in side by side format by the display controller;

FIG. 8 is an example of an image display of the Spec logic circuit and the Impl logic circuit after changing from one below the other format to the side by side format by the display controller;

FIG. 9 is an example of an image display of the Spec logic circuit and the Impl logic circuit after changing from the side by side format to the one below the other format by the display controller;

FIG. 10 is an example of a display of images arranged side by side by the display controller, after linking and enlarging display areas of the Spec logic circuit and the Impl logic circuit;

FIG. 11 is a flowchart of a circuit diagram display procedure executed by the circuit diagram display apparatus;

FIG. 12 is a functional block diagram of a structure of a circuit diagram display apparatus according to a second embodiment;

FIG. 13A is an example of network information of a Spec logic circuit stored in a Spec structural information storage shown in FIG. 12;

FIG. 13B is an example of port information of the Spec logic circuit stored in a Spec structural information storage shown in FIG. 12;

FIG. 14 is an example of a display of the Spec logic circuit and the Impl logic circuit, associated based on the network information and the port information shown in FIGS. 13A and 13B;

FIG. 15 is a flowchart of a circuit diagram display procedure executed by the circuit diagram display apparatus;

FIG. 16 is a functional block diagram of a structure of a circuit diagram display apparatus according to a third embodiment;

FIG. 17 is an example of logical equivalence information stored in a logical equivalence information storage shown in FIG. 16;

FIG. 18 is an example of a display of the Spec logic circuit and the Impl logic circuit associated based on the logical equivalence information stored in the logical equivalence information storage shown in FIG. 16;

FIG. 19 is a flowchart of a circuit diagram display procedure executed by the circuit diagram display apparatus shown in FIG. 16;

FIG. 20 is a functional block diagram of a structure of a circuit diagram display apparatus according to a fourth embodiment;

FIG. 21 is an example of a display of a Spec logic circuit and an Impl logic circuit associated based on external designated information stored in an external designated information storage shown in FIG. 20;

FIG. 22 is a flowchart of an external designation procedure for storing the external designated information in the external designated information storage;

FIG. 23 is a flowchart of a circuit diagram display procedure executed by the circuit diagram display apparatus;

FIG. 24 is a functional block diagram of a structure of a circuit diagram display apparatus according to a fifth embodiment;

FIG. 25 is an example of a display of a plurality of logic circuits associated based on identification information, structural information, logical equivalence information, and external designated information by the circuit diagram display apparatus shown in FIG. 24; and

FIG. 26 is a flowchart of a circuit diagram display procedure executed by the circuit diagram display apparatus shown in FIG. 24.

### DETAILED DESCRIPTION

Exemplary embodiments of an apparatus and a method for circuit diagram display and a computer product according to the present invention are described in detail below with reference to accompanying drawings.

A first embodiment describes the side by side display of the plurality of circuit diagrams that are associated based on the identification information of the logic circuits by the circuit diagram display apparatus.

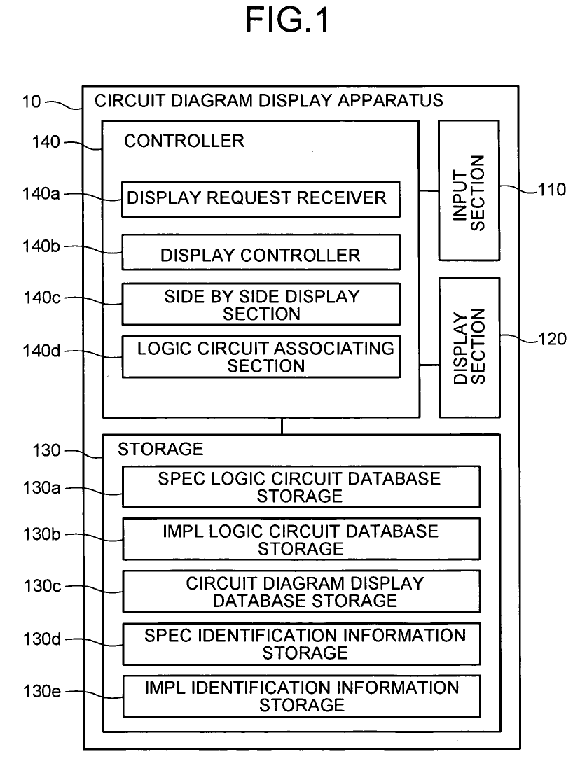

To start with, an outline and main features of the circuit diagram display apparatus are described with reference to FIG. 1. FIG. 1 is a functional block diagram of a circuit diagram display apparatus 10 according to the first embodiment. The circuit diagram display apparatus 10 displays a plurality of circuit diagrams, and is structured not only for a display in one below the other format as in the conventional technology, but also for a display in a side by side format. Concretely, when circuit areas of each circuit diagram are displayed in the one below the other format or in the side by side format, executing a command once can switch between the display formats. While changing the display format, a display control is performed to hold a target point that is included in the circuit area after the change, in the same position as the target point that is included in the circuit area before the change. The display control is performed in such a manner that enables to change the display that is suitable for a shape and a range of debugging of the two circuits, thereby improving the efficiency of operation. Moreover, the target points are held so that there is no interruption in thinking of the designer before and after the change, and the debugging efficiency improves.

For letting the whole of each circuit diagram to be displayed as a circuit area, a judgment of whether each circuit area is to be displayed in the one below the other format or the side by side format is made based on an aspect ratio of each circuit diagram. Based on the decision made, the display format is changed from the one below the other format to the side by side format or vice versa by executing the command once. The display control is performed in this manner to display the circuit diagrams in a display format that is suitable for the shape of the circuit diagrams, and to improve the efficiency of operation.

A rectangular area, which is a part of each circuit diagram, and which is designated by a user can be displayed as a circuit area. A judgment of whether each circuit area is to be displayed in the one below the other format or in the side by side format is made based on an aspect ratio of each rectangular area. Based on the judgment made, the display format is changed from the one below the other format to the side by side format or vice versa by executing the command once. The display control is performed in this manner to display the circuit diagrams in a display format that is suitable for the rectangular area even when the user designates a part of the circuit diagram as the rectangular area, and to improve the efficiency of operation.

Through such display controls, corresponding locations of logic circuits to be compared in logical equivalence verification of the plurality of logic circuits are displayed efficiently, and the efficiency of debugging by the designer improves.

The plurality of circuit diagrams is a plurality of logic circuit diagrams. A logic circuit associating section 140d associates the plurality of logic circuits based on at least any one of identification information, structural information, logical equivalence information, and external designated information related to the logic circuit. A side by side display section 140c displays the plurality of logic circuits arranged side by side. A display controller 140b performs control in such a manner that the logic circuit diagrams that are associated by the logic circuit associating section 140d are displayed side by side by the side by side display section 140c, based on at least any one of a display area related to the circuit diagram, a center of the display area, and a display request. The control being performed in such a manner, the locations corresponding to the logic circuit compared in the logical equivalence verification of the plurality of logic circuits are displayed efficiently.

A structure of the circuit diagram display apparatus 10 according to the first embodiment is described below with reference to FIG. 1. The circuit diagram display apparatus 10 is a personal computer that displays images of the plurality of circuit diagrams. The circuit diagram display apparatus 10 includes an input section 110, a display section 120, a storage 130, and a controller 140.

The input section 110 is an input device such as a keyboard and a mouse, and inputs a user's request, instruction, and data. The display section 120 is a circuit diagram display device such as an LCD (Liquid Crystal Display) that displays the plurality of logic circuits.

The storage 130, which is a storage device such as an IC (Integrated Circuit) memory, HDD (Hard Disk Drive), includes a Spec logic circuit database storage 130a, an Impl logic circuit database storage 130b, a circuit diagram display database storage 130c, a Spec identification information storage 130d, and an Impl identification information storage 130e.

The Spec logic circuit database storage 130a stores Spec logic circuit database. The Impl logic circuit database storage 130b stores Impl logic circuit database. The Spec logic circuit database is logic circuit data called as Spec for performing a predetermined function in a layout design of the logic circuit such as an LSI. Whereas, the Impl logic circuit database is logic circuit data called as Impl (Implementation) obtained by modifying a structure without changing the function of the Spec logic circuit to deal with various constraints related to number of gates, delay time etc. It is necessary that the Impl logic circuit have predetermined functions equivalent to those of the Spec logic circuit. Therefore, logical equivalence verification is performed to verify logical equivalence of the Impl logic circuit and the Spec logic circuit. The circuit diagram display apparatus 10 according to the first embodiment is used in the logical equivalence verification.

The circuit diagram display database storage 130c stores circuit diagram display database in which the Spec logic circuit database and the Impl logic circuit database are associated with symbols of the logic circuit for preparing the logic circuit diagram, position coordinates and size of a world coordinate system of the symbols. The world coordinate system is described separately in detail.

The Spec identification information storage 130d stores Spec identification information that associates the logic circuit of the Spec logic circuit database with the identification information of the logic circuit. Because the Spec logic circuit data is logic circuit data that is described in an HDL (Hardware Description Language), the identification information of the logic circuit is name of a module, name of an instance, and name of a port. The module is a unit of design of the logic circuit, and an OR circuit, an AND circuit are examples of module. The instance is a reference name that cites a module in the logic circuit data that is described in the HDL. The port is an input-output terminal of the logic circuit.

The Impl identification information storage 130e stores identification information that associates the logic circuit of the Impl logic circuit database with the identification information of the logic circuit. The identification information of the Impl logic circuit is similar to that of the Spec logic circuit, and includes name of a module, name of an instance, and name of a port.

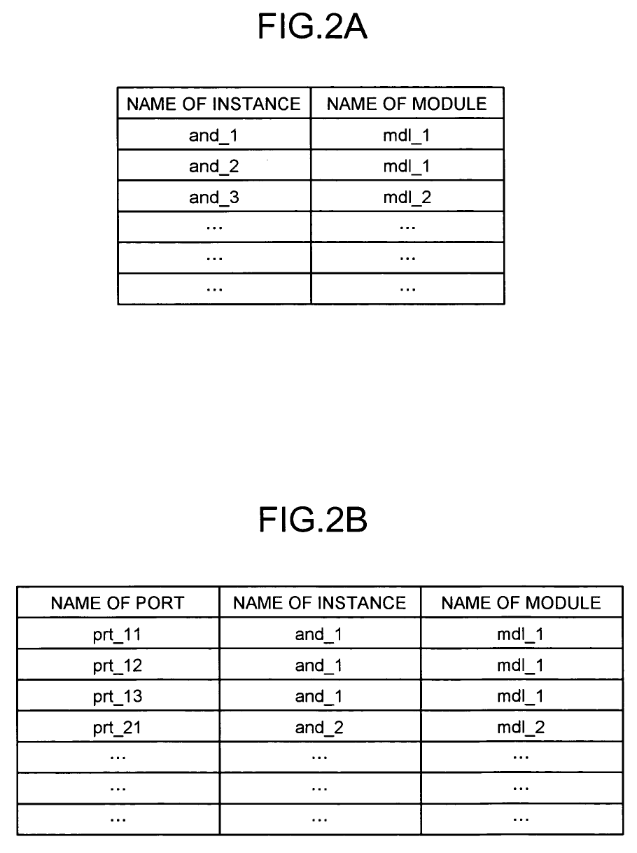

FIGS. 2A and 2B are examples of the identification information of modules and ports stored in the Spec identification information storage 130d and the Impl identification information storage 130e shown in FIG. 1. The identification information of the logic circuit includes the identification information of modules and the identification information of ports. The identification information of the modules and ports is for the Spec logic circuit database and the Impl logic circuit database respectively, and is common for both except for a part of the logic circuit. Therefore, is described collectively by referring to FIGS. 2A and 2B.

As shown in FIG. 2A, the name of the instance is associated with the name of the module. The Spec logic circuit and the Impl logic circuit have the same instance name and module name. While making a unique judgment, both the modules are judged as associated.

As shown in FIG. 2B, regarding the ports, it is quite possible that there is a plurality of same names. Therefore, the name of port, the name of instance to which the port belongs, and the name of module are associated. The Spec logic circuit and the Impl logic circuit have the same port name, instance name, and the module name respectively, and when a judgment is to be made uniquely, both the ports are judged as associated.

Returning to the description of FIG. 1, the controller 140 controls the circuit diagram display apparatus 10, and includes a display request receiver 140a, the display controller 140b, the side by side display section 140c, and the logic circuit associating section 140d. The display request receiver 140a receives a display request made by the user, and receives a display request to change a direction of display of the Spec logic circuit and the Impl logic circuit.

The display controller 140b provides control to display the circuit diagrams of the Spec logic circuit and the Impl logic circuit side by side, based on at least any one of the display area related to the circuit diagram, the center of the display area, and the display request. Moreover, the display controller 140b provides control to perform a linked display of the circuit diagrams of the Spec logic circuit and the Impl logic circuit according to the display request. The display controller 140b also performs control such that the center of the display area related to the circuit diagrams of the logic circuits of the Spec logic circuit and the Impl logic circuits becomes a center of an image. The display controller 140b performs control to change the direction of display of the circuit diagrams of the Spec logic circuit and the Impl logic circuit according to the display request.

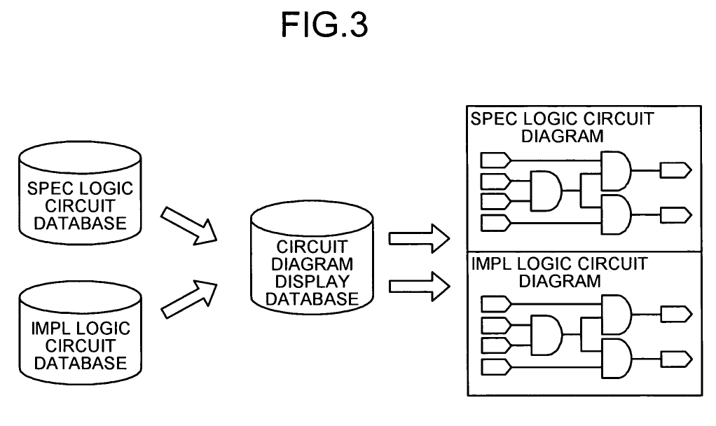

The side by side display section 140c is a controller that displays the circuit diagrams of the logic circuits of the Spec logic circuit and the Impl logic circuit associated by the logic circuit associating section 140d. The following is a description, with reference to FIG. 3, of an example of the side by side display of the circuit diagrams based on the logic circuit database and the circuit diagram display database, displayed by the side by side display section 140c shown in FIG. 1. FIG. 3 is an example of a side by side display of circuit diagrams, displayed by the side by side display section shown in FIG. 1, based on the logic circuit database and the circuit diagram display database. The side by side display section 140c creates a symbol of the logic circuit based on the Spec logic circuit database and the Impl logic circuit database, and stores, in the circuit diagram display database storage 130c, the circuit diagram display database in which the symbol created is associated with position coordinate and size of the world coordinate system of the symbol. Moreover, the side by side display section 140c performs coordinate conversion of circuit diagram display data from the world coordinate system to a screen coordinate system, and displays the Spec logic circuit and the Impl logic circuit side by side on a display screen of the display section 120. The world coordinate system and the screen coordinate system are described separately in detail.

Returning to FIG. 1, the logic circuit associating section 140d associates the Spec logic circuit and the Impl logic circuit based on at least any one of the identification information, the structural information, the logical equivalence information, and the external designated information related to the logic circuit. Moreover, the logic circuit associating section 140d associates the Spec logic circuit and the Impl logic circuit based on the identification information.

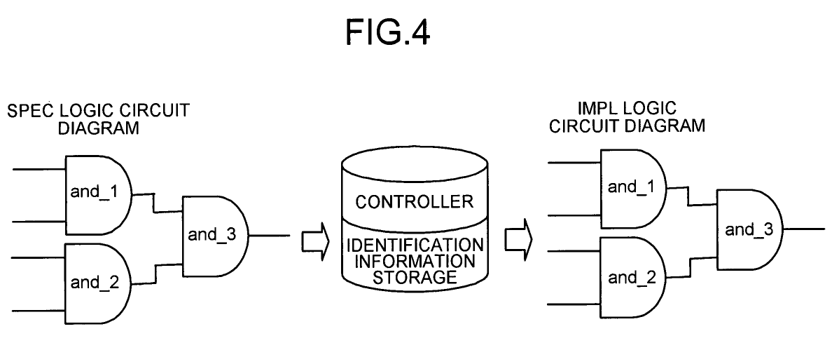

The following is a description of an example where associated the Spec logic circuit and the Impl logic circuit are displayed by the circuit diagram display apparatus 10 shown in FIG. 1 based on the identification information. FIG. 4 is an example of associated Spec logic circuit and Impl logic circuit displayed by the circuit diagram display apparatus shown in FIG. 1 based on the identification information.

As shown in FIG. 4, when the user designates a logic circuit and_1 from a display screen of the Spec logic circuit using the input section 110, for example, by clicking with a mouse, the display controller 140b controls the side by side display section 140c so that the side by side display section 140c selects a corresponding instance name and_1 from the Impl identification information storage 130e shown in FIG. 1, and highlights the instance name and_1.

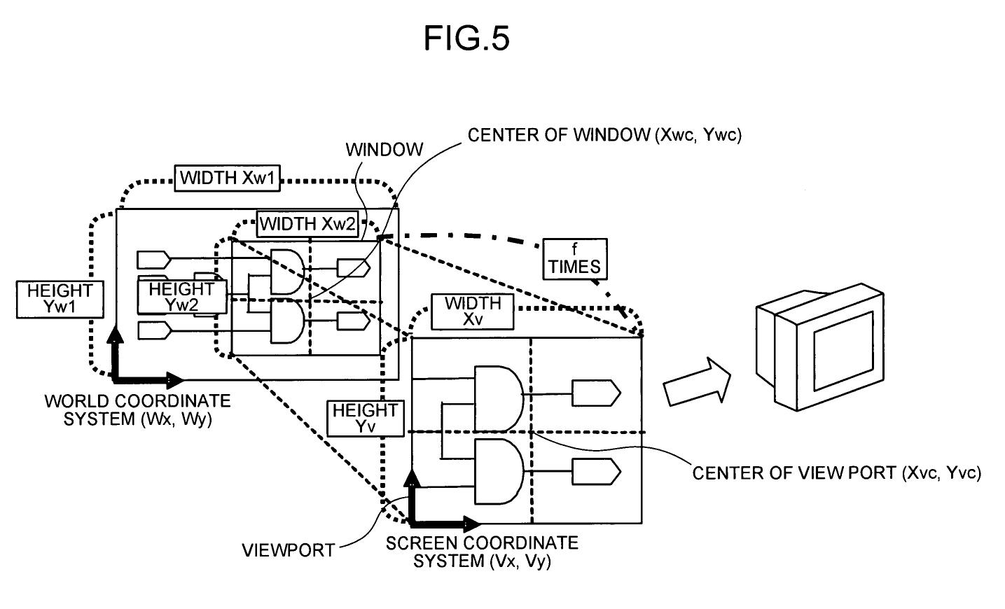

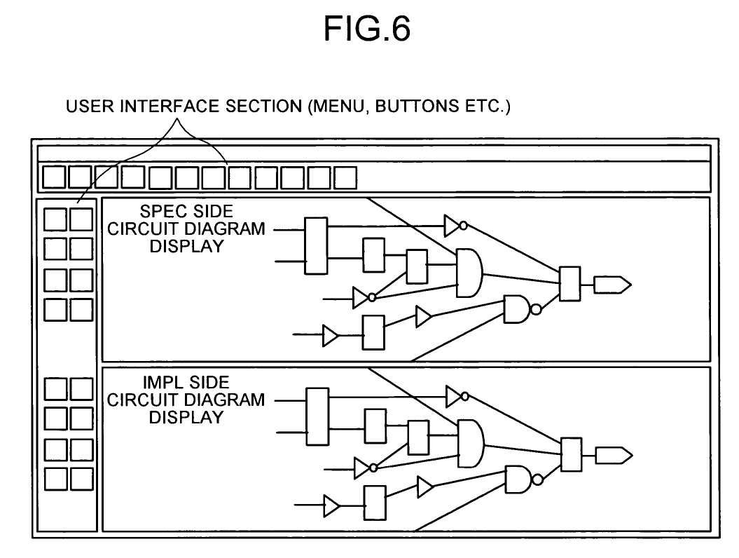

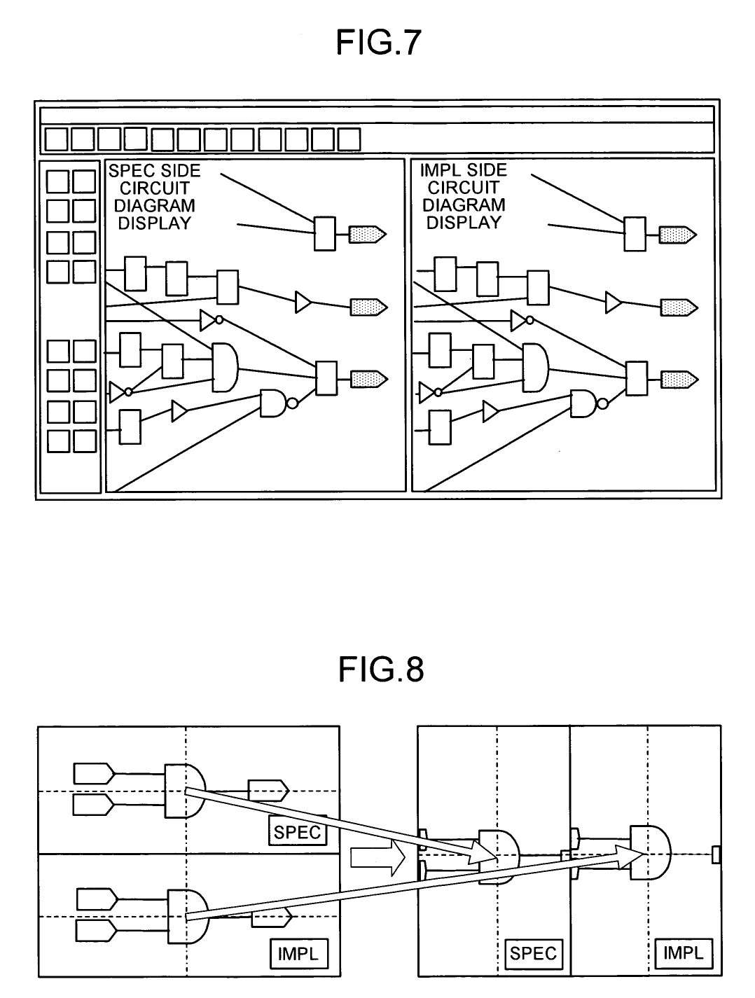

The following is a description of an example of an image display of the Spec logic circuit and the Impl logic circuit by the display controller 140b shown in FIG. 1, with reference to FIGS. 5 to 9. FIG. 5 is an example of an image display where the Spec logic circuit and the Impl logic circuit are converted from the world coordinate system to the screen coordinate system by the display controller 140b. FIG. 6 is an example of an image display of the Spec logic circuit and the Impl logic circuit arranged in one below the other format by the display controller 140b. FIG. 7 is an example of an image display of the Spec logic circuit and the Impl logic circuit arranged in side by side format by the display controller 140b.

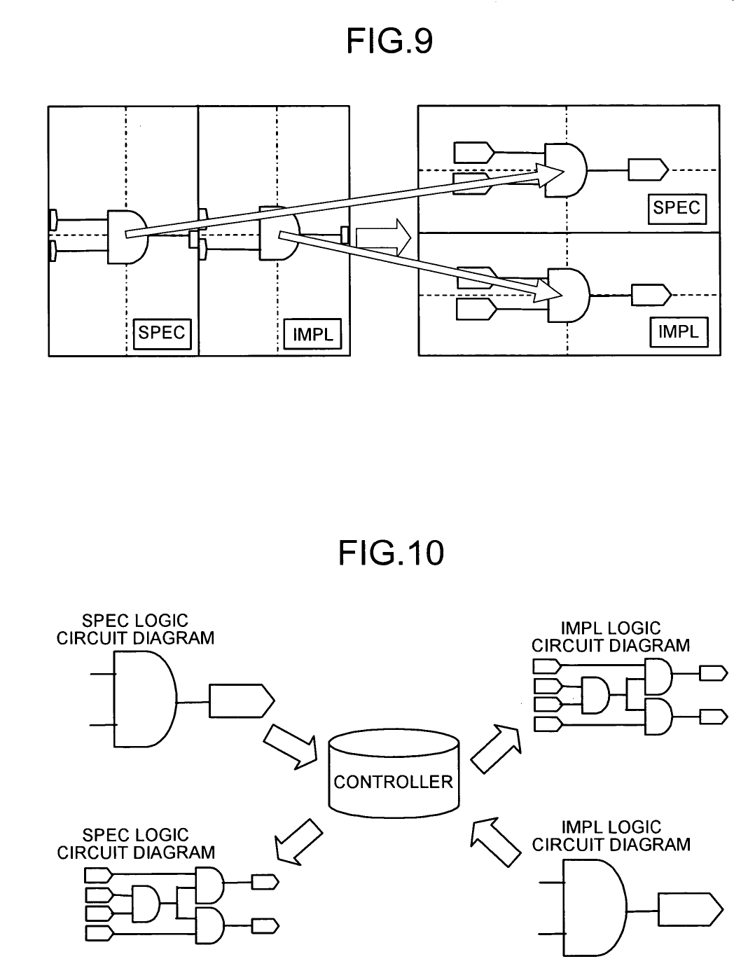

FIG. 8 is an example of an image display of the Spec logic circuit and the Impl logic circuit after changing from the one below the other format to one on the side of the other format by the display controller 140b. FIG. 9 is an example of an image display of the Spec logic circuit and the Impl logic circuit after changing from one on the side of the other format to one below the other format by the display controller 140b. The following is a description with reference to FIGS. 5 to 9.

As shown in FIG. 5, for displaying the logic circuit diagram on the display section 120, the user designates a display area of the logic circuit using the input section 110. Concretely, the User inputs an instance name to be displayed, using the keyboard. Or, the user displays a hierarchical tree that illustrates a hierarchical structure of instances, and clicks an instance to be displayed from the hierarchical tree, by using the mouse. Or, the user displays either the Spec logic circuit or the Impl logic circuit on the display section 120, and clicks an instance to be displayed from the Spec logic circuit or from the Impl logic circuit, or designates the display area.

When the display area of the logic circuit is designated using the input section 110, the side by side display section 140c finds a symbol of the logic circuit included in the display area designated, from the circuit diagram display database. Moreover, the side by side display section 140c converts from a window to a view port, based on the size and the position coordinates of the world coordinate system of the symbol of the logic circuit, and finds a size and position coordinates of the screen coordinate system. Furthermore, the side by side display section 140c displays an image of the logic circuit on a screen of the display section 120 based on the size and the position coordinates of the symbol that are converted to the screen coordinate system.

The following is a description of the world coordinate system and the screen coordinate system. The world coordinate system (Wx, Wy) is used for storing information of the relative position and size of symbols of the logic circuit. Whereas, the screen coordinate system (Vx, Vy) is used for finding a size and a position of a symbol for actually displaying on the screen. The conversion of a window that is a display area designated by the user and a view port that is a display screen of the display section 120 is performed, and an image of the logic circuit is displayed on the display screen of the display section 120. Thus, the user can see the logic circuit as an image in the screen coordinate system.

For example, if the display request receiver 140a receives a request to display the entire logic circuit, the display controller 140b calculates height Yw1 and width Xw1 of the world coordinate system. If the width is longer than the height, the image is displayed by arranging in the one below the other format as shown in FIG. 6. If the height is longer than the width, the image is displayed by arranging in the side by side format as shown in FIG. 7.

If the display request receiver 140a receives a request to change the image display of the entire logic circuit from the one below the other format to the side by side format or vice versa, the display controller 140b automatically changes the image display of the entire logic circuit from the one below the other format to the side by side format as shown is FIG. 8, or from the side by side format to the one below the other format as shown in FIG. 9.

Thus, the display controller 140b is not only able to display the image with a plurality of images arranged side by side on the screen of the display section 120, but can also change the image display from the one below the other format to the side by side format, and vice versa. Therefore, the circuit diagram display apparatus 10 can change the image display according to the display area and the shape of the logic circuit by a single operation, thereby improving the efficiency of operation considerably.

When the display request receiver 140a receives a request from the user for changing the display format, the display controller 140b applies a correction to the side by side display section 140c so that a center of a view port after the change in the display format coincides with a center of a view port before the change in the display format.

Concretely, the side by side display section 140c stores coordinate value (Xwc, Ywc) of a center of the window before changing the image display. After the change in the image display, the size of the view port is determined from the size (Xv, Yv) of the display screen of the display section 120. Moreover, the side by side display section 140c modifies the size of the view port and the size (Xw2, Yw2) of the window based on a conversion power f, from the world coordinate system to the screen coordinate system without changing the center (Xwc, Ywc) of the window. Further, the display of the view port is modified based on the window after the modification of size.

Thus the display controller 140b applies the correction to the side by side display section 140c so that the center of the view port after the change coincides with the center of the view port before the change. Therefore, there is no interruption of analysis by the circuit diagram display apparatus 10 due to shifting of the display position on the screen of a part for which the screen display is to be changed, and the efficiency of operation is improved considerably.

When the display request receiver 140a receives a request from the user for displaying an image of a rectangular display area, and if the width of the rectangular display area designated by the user is longer than the height of the rectangular display area, then the display controller 140b displays the image in the one below the other format as shown in FIG. 6. If the height of the rectangular display area is longer than the width, the display controller 140b displays the image in the side by side format as shown in FIG. 7.

Thus, the display controller 140b determines the aspect ratio of the rectangular display area designated by the user, to change automatically from the one below the other format to the side by side format, and causes the side by side display section 140c to display the images side by side. Therefore, once the images are displayed in any one of the formats, there is no need to change manually to the other format according to the rectangular display area designated, and thus the efficiency of operation of the circuit diagram display apparatus 10 improves.

Upon receiving display requests such as linking/unlinking, scroll, enlargement/reduction of display area, reset of circuit diagram display, zoom in and zoom out of circuit diagram, which are received from the user via the display request receiver 140a, the display controller 140b can display the Spec logic circuit and the Impl logic circuit accordingly. An example of the display of images arranged side by side upon linking and enlarging display areas of the Spec logic circuit and the Impl logic circuit by the display controller 140b is described below with reference to FIG. 10. FIG. 10 is an example of a display of images arranged side by side by the display controller 140b, upon linking and enlarging display areas of the Spec logic circuit and the Impl logic circuit.

As shown in FIG. 10, when the display request receiver 140a receives a request from the user for linking and enlarging the display area, the display controller 140b controls the side by side display section 140c to link and enlarge the Spec logic circuit and the Impl logic circuit. Further, the side by side display section 140c links and enlarges the display areas of the Spec logic circuit and the Impl logic circuit, and displays the display areas side by side on the display section 120.

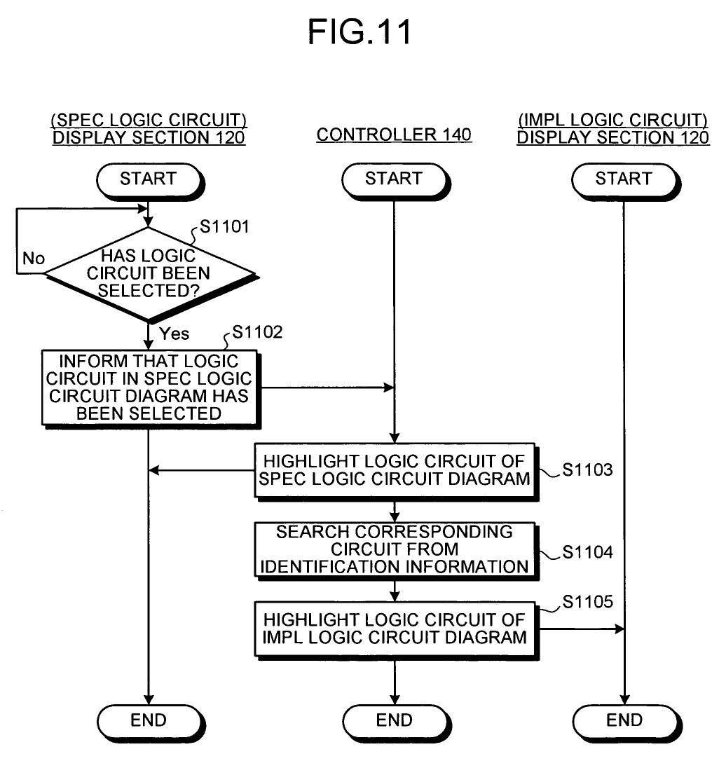

A circuit diagram display procedure executed by the circuit diagram display apparatus 10 shown in FIG. 1 is described below with reference to the flowchart shown in FIG. 11. The circuit diagram display procedure is performed when the user selects a logic circuit from Spec logic circuits displayed on the display section 120.

As shown in FIG. 11, the (Spec logic circuit) display section 120 waits till the user selects the logic circuit (step S1101). For example, the user selects a logic circuit in the Spec logic circuit diagram on the screen by clicking with the mouse.

If the user selects the logic circuit (Yes at step S1101), the display section 120 informs the display controller 140b that the logic circuit in the Spec logic circuit diagram has been selected (step S1102). The display controller 140b then highlights the logic circuit selected by the user (step S1103). Further, the logic circuit associating section 140d searches a logic circuit in the Impl logic circuit diagram corresponding to the logic circuit selected, based on the identification information (step S1104), and the display controller 140b highlights the corresponding logic circuit in the Impl logic circuit diagram (step S1105). Concretely, the display controller 140b highlights by changing the color of the display of the corresponding logic circuit.

Thus, the logic circuit associating section 140d is made to associate the logic circuit in the Spec logic circuit diagram with the logic circuit in the Impl logic circuit diagram. Therefore, the circuit diagram display apparatus 10 can display efficiently, the corresponding location of the logic circuit compared.

Thus, according to the first embodiment, the logic circuit associating section 140d associates the logic circuit in the Spec logic circuit diagram with the logic circuit in the Impl logic circuit diagram based on the identification information related to the logic circuit in the Spec logic circuit diagram and the logic circuit in the Impl logic circuit diagram. The side by side display section 140c displays side by side, the circuit diagrams of the logic circuit in the Spec logic circuit diagram and the logic circuit in the Impl logic circuit diagram. The display controller 140b performs the control in such a manner that the side by side display section 140c accordingly displays the circuit diagrams of the logic circuit in the Spec logic circuit diagram and the logic circuit in the Impl logic circuit diagram that are associated by the logic circuit associating section 140d based on at least any one of the display area related to the circuit diagram, the center of the display area, and the display request. Therefore, the circuit diagram display apparatus 10 can display efficiently, the corresponding locations of the logic circuits compared.

Moreover, because the logic circuit associating section 140d is made to associate the logic circuit in the Spec logic circuit diagram and the logic circuit in the Impl logic circuit diagram based on the identification information, the circuit diagram display apparatus 10 can display efficiently, the corresponding locations of the logic circuits compared. In the first embodiment, a case of selection of the Spec logic circuit by the user has been described. However, the present invention is not restricted to this case, and can also be applied to a case of selection of the Impl logic circuit by the user. The same is applicable to the embodiments from the second embodiment to the fifth embodiment.

The second embodiment describes the side by side display of the plurality of circuit diagrams that are associated based on the structural information of the logic circuits by the circuit diagram display apparatus.

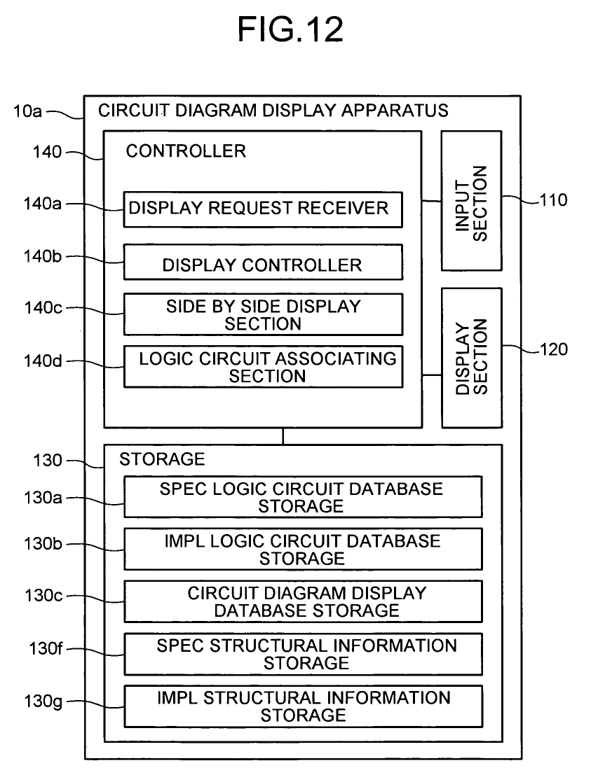

A structure of a circuit diagram display apparatus 10a according to the second embodiment is described below with reference to FIG. 12. FIG. 12 is a functional block diagram of the structure of the circuit diagram display apparatus 10a according to the second embodiment. The structure includes a Spec structural information storage 130f and an Impl structural information storage 130g, which are not there in the functional block diagram of the first embodiment. The following is a description of the Spec structural information storage 130f and the Impl structural information storage 130g.

The Spec structural information storage 130f stores structural information of the Spec logic circuit and the Impl structural information storage 130g stores structural information of the Impl logic circuit. The structural information of the logic circuit specifies the circuit structure of the logic circuit, and includes network information and port information.

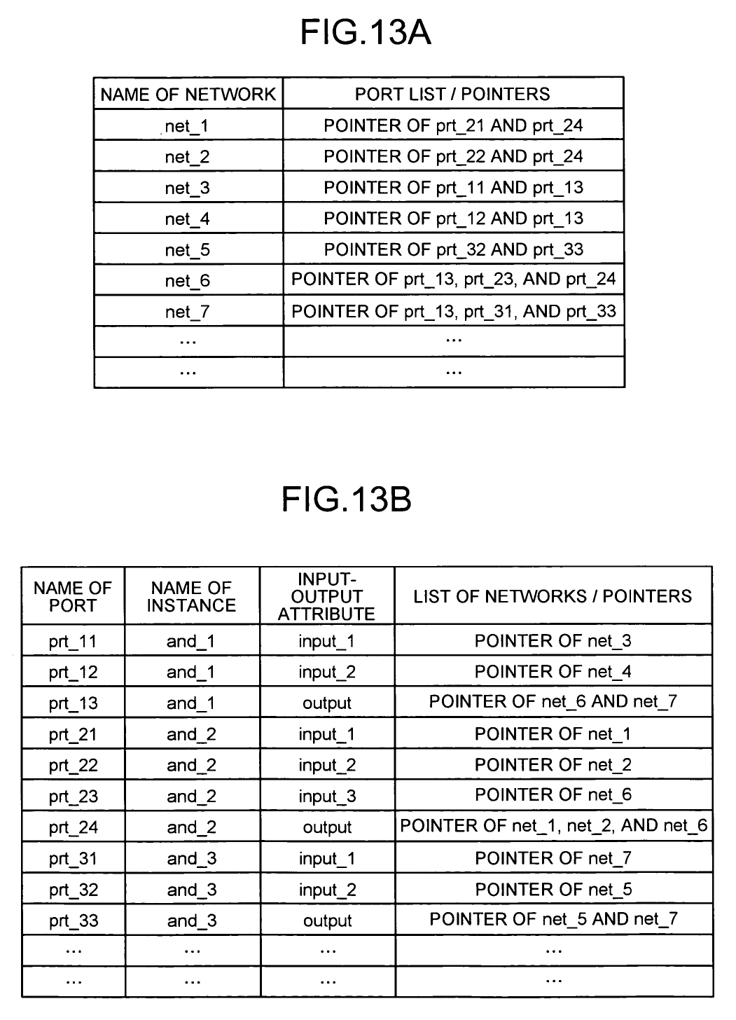

The Spec structural information stored in the Spec structural information storage 130f shown in FIG. 12 is described with reference to FIGS. 13A and 13B. FIG. 13A is an example of the network information of the Spec logic circuit stored in the Spec structural information storage 130f. FIG. 13B is an example of the port information of the Spec logic circuit stored in the Spec structural information storage 130f. The network information includes networks associated with lists and pointers related to ports that are connected to the network. The port information includes ports associated with instances, input-output attributes of the ports, and lists and pointers related to the networks that are connected to the ports.

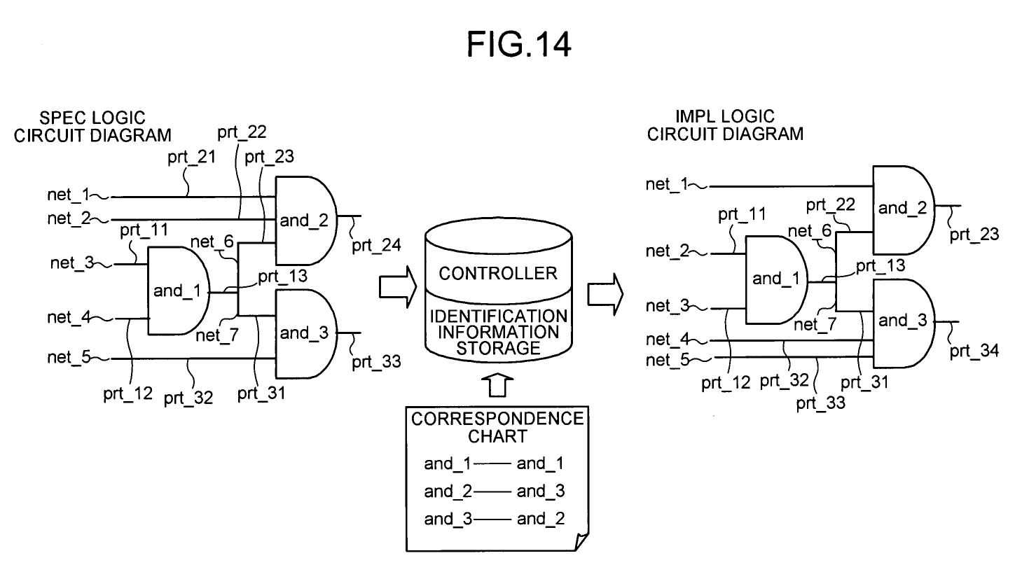

An example of a display of the Spec logic circuit and the Impl logic circuit associated based on the network information and the port information shown in FIGS. 13A and 13B is described below with reference to FIG. 14. FIG. 14 is an example of the display of the Spec logic circuit and the Impl logic circuit, associated based on the network information and the port information shown in FIGS. 13A and 13B.

A port prt_13 shown in the Spec logic circuit in FIG. 14 is an output terminal output of an instance and_1 as shown in FIG. 13B, and is connected to networks net_6 and net_7. Further, if an access is made to a pointer of the network net_6 in FIG. 13A, it can be seen that a port prt_13 from a port list of the network net_6 is connected to ports prt_23 and prt_24 of an instance and_2. Moreover, the instance and_2 has three input terminals input_1, input_2, and input_3, and one output terminal output. This is evident from the Spec logic circuit shown in FIG. 14.

On the other hand, such kind of network information and port information is available for the Impl logic circuit as well. From such information, a connection is made to a port prt_13 of an instance and_1 of the Impl logic circuit, and an instance and_3 that has three input terminals and one output terminal corresponding to the instance and_2 of the Spec logic circuit. Similarly, it can be seen that the instance and_2 of the Impl logic circuit corresponds to an instance and_3 of the Spec logic circuit. This is evident from the Impl logic circuit shown in FIG. 14. Thus, the logic circuit of the Spec logic circuit and the logic circuit of the Impl logic circuit are associated by one to one relationship based on the network information and the port information.

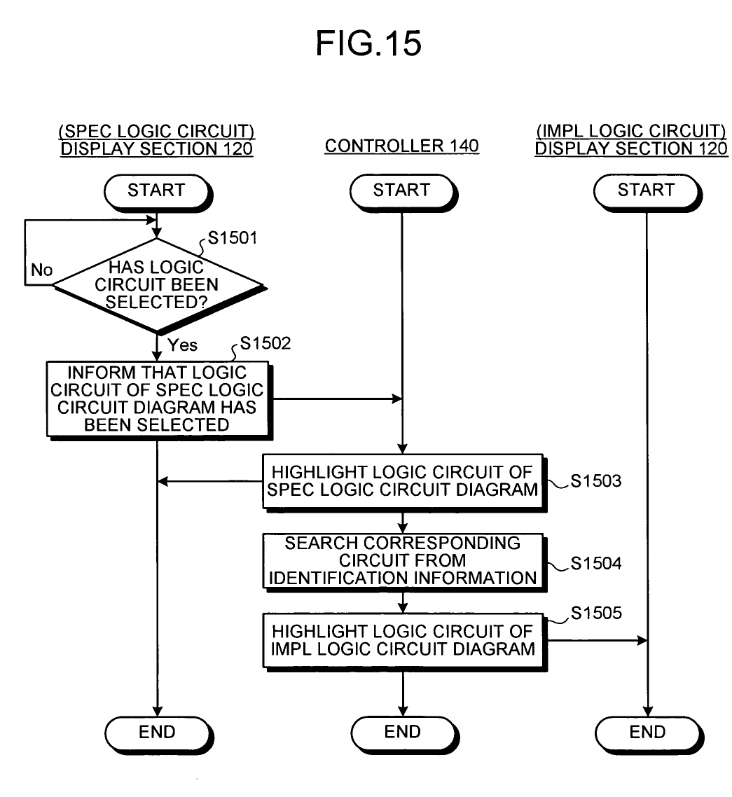

A circuit diagram display procedure of the circuit diagram display apparatus 10a shown in FIG. 12 is described below with reference to the flowchart shown in FIG. 15. The circuit diagram display procedure is performed when a user selects a logic circuit from the Spec logic circuits that are displayed on the display section 120.

As shown in FIG. 15, the (Spec logic circuit) display section 120 waits till the user selects the logic circuit (step S1501). The user selects a logic circuit in the Spec logic circuit diagram on the screen by clicking with the mouse.

If the user selects the logic circuit (Yes at step S1501), the display section 120 informs the display controller 140b that the logic circuit in the Spec logic circuit diagram has been selected (step S1502). The display controller 140b then highlights the logic circuit selected by the user (step S1503). Concretely, the display controller 140b highlights the corresponding logic circuit by changing the color of the display. Further, the logic circuit associating section 140d searches a logic circuit in the Impl logic circuit diagram corresponding to the logic circuit that is selected, based on the Spec structural information and the Impl structural information (step S1504), and the display controller 140b highlights the corresponding logic circuit in the Impl logic circuit diagram (step S1505).

Thus, according to the second embodiment, the logic circuit associating section 140d is made to associate the logic circuit in the Spec logic circuit diagram with the logic circuit in the Impl logic circuit diagram. Therefore, the circuit diagram display apparatus 10a can display efficiently, the corresponding location of the logic circuit compared.

The third embodiment describes the side by side display of the plurality of circuit diagrams that are associated based on the logical equivalence information of the logic circuit by the circuit diagram display apparatus.

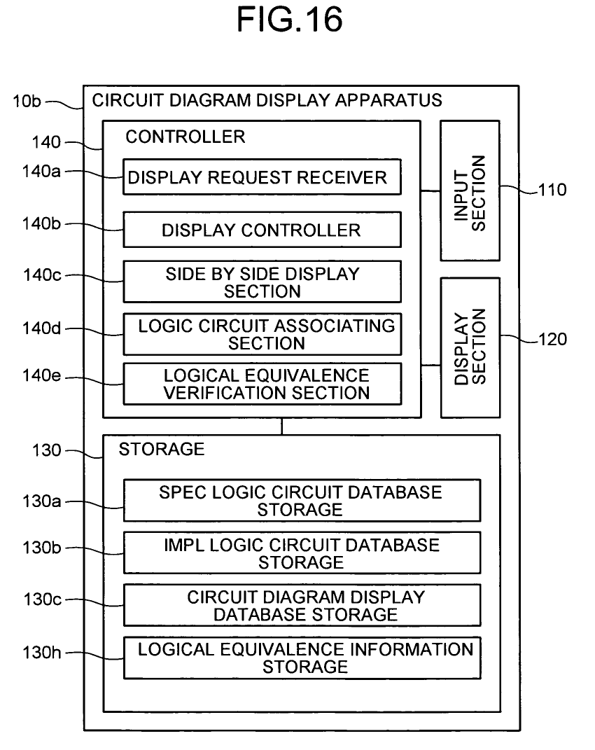

A structure of a circuit diagram display apparatus 10b according to the third embodiment is described below with reference to FIG. 16. FIG. 16 is a functional block diagram of a structure of the circuit diagram display apparatus 10b according to the third embodiment. The structure includes a logical equivalence information storage 130h and a logical equivalence verification section 140e, which are not there in the functional block diagram of the first embodiment. The following is a description of the logical equivalence information storage 130h and the logical equivalence verification section 140e.

The logical equivalence information storage 130h stores logical equivalence information that associates logical equivalence of the Spec logic circuit and the Impl logic circuit. The logical equivalence verification section 140e verifies logical equivalence of the Spec logic circuit and the Impl logic circuit. The logical equivalence verification section 140e further compares the Spec logic circuit and the Impl logic circuit to check whether a logic that determines signal values of an external output terminal, a storage element terminal, an input-output terminal of an instance that is hierarchized, and a terminal that is designated from outside, are the same.

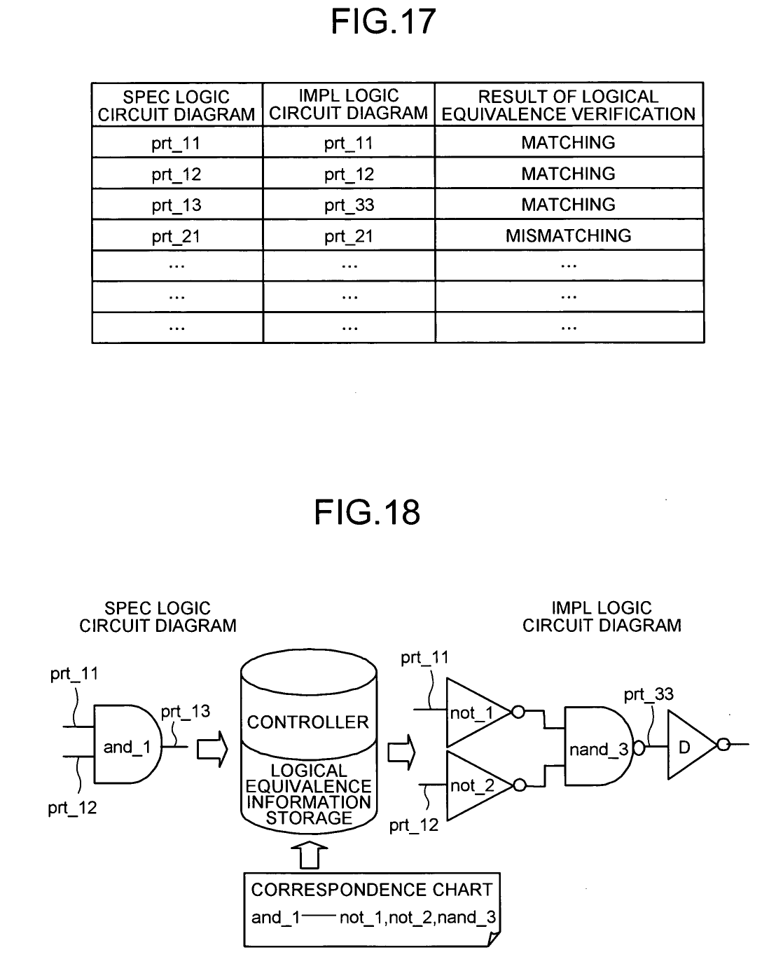

The logical equivalence information stored in the logical equivalence information storage 130h shown in FIG. 1 is described below with reference to FIG. 17. FIG. 17 is an example of the logical equivalence information stored in the logical equivalence information storage 130h. The logical equivalence information storage 130h associates corresponding ports of the Spec logic circuit and the Impl logic circuit with a result of the logical equivalence verification of the ports. Therefore, if the result of the logical equivalence verification matches, the corresponding ports of the Spec logic circuit and the Impl logic circuit are equivalent theoretically. If the result of the logical equivalence verification does not match, the corresponding ports of the Spec logic circuit and the Impl logic circuit are not equivalent theoretically.

An example of a display of the Spec logic circuit and the Impl logic circuit associated based on the logical equivalence information stored in the logical equivalence information storage 130h shown in FIG. 16 is described below with reference to FIG. 18. FIG. 18 is the example of the display of the Spec logic circuit and the Impl logic circuit associated based on the logical equivalence information stored in the logical equivalence information storage 130h. As shown in FIG. 18, ports prt_11 and prt_12 of an instance and_1 of the Spec logic circuit are input terminals, and correspond to ports prt_11 and prt_12 of the Impl logic circuit. On the other hand, a port prt_33 (see FIG. 17) of the Impl logic circuit corresponds to a port prt_13 of the instance and_1 of the Spec logic circuit, and the result of the logical equivalence verification is ‘matched’. Therefore, it can be seen that the instance and_1 of the Spec logic circuit corresponds to instances not_1, not_2, and nand_3 of the Impl logic circuit.

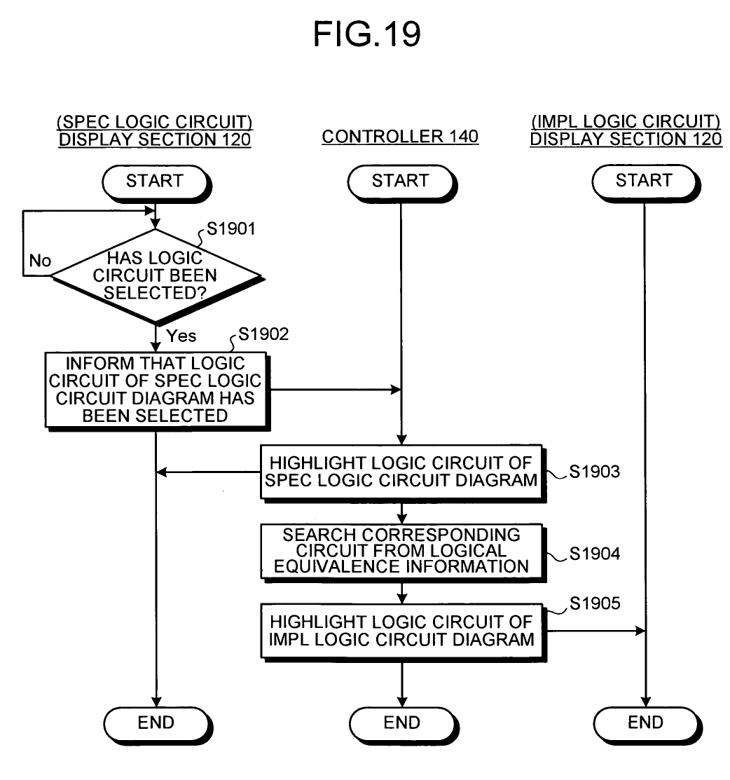

A circuit diagram display procedure executed by the circuit diagram display apparatus 10b shown in FIG. 16 is described below with reference to the flowchart shown in FIG. 19. The circuit diagram display procedure is performed when a user selects a logic circuit from the Spec logic circuits that are displayed on the display section 120.

As shown in FIG. 19, the (Spec logic circuit) display section 120 waits till the user selects the logic circuit (step S1901). The user selects a logic circuit in the Spec logic circuit diagram on the screen by clicking with the mouse.

If the user selects the logic circuit (Yes at step S1901), the display section 120 informs the display controller 140b that the logic circuit in the Spec logic circuit diagram has been selected (step S1902). The display controller 140b then highlights the logic circuit selected by the user (step S1903). Concretely, the display controller 140b highlights the logic circuit by changing the color of the display. Further, the logic circuit associating section 140d searches a logic circuit in the Impl logic circuit diagram corresponding to the logic circuit selected, based on the logical equivalence information (step S1904), and the display controller 140b highlights the corresponding logic circuit in the Impl logic circuit diagram (step S1905).

Thus, the logic circuit associating section 140d is made to associate the logic circuit in the Spec logic circuit diagram with the logic circuit in the Impl logic circuit diagram, based on the logical equivalence information. Therefore, the circuit diagram display apparatus 10b can display efficiently, the corresponding location of the logic circuit compared.

Thus, according to the third embodiment, the logic circuit associating section 140d is made to associate the logic circuit in the Spec logic circuit diagram with the logic circuit in the Impl logic circuit diagram. Therefore, the circuit diagram display apparatus 10b can display efficiently, the corresponding location of the logic circuit compared.

The fourth embodiment describes the side by side display of the plurality of circuit diagrams that are associated based on externally designated information of the logic circuits, by the circuit diagram display apparatus.

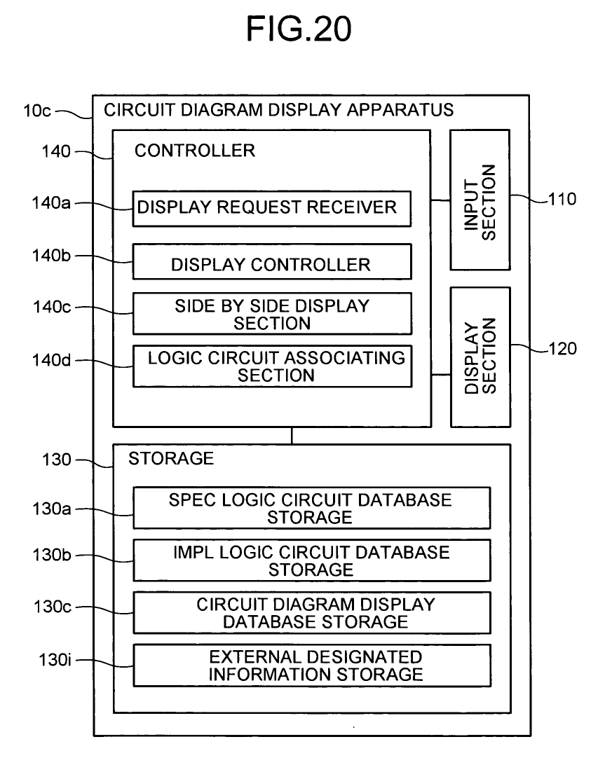

A structure of a circuit diagram display apparatus 10c according to the fourth embodiment is described below with reference to FIG. 20. FIG. 20 is a functional block diagram of the structure of the circuit diagram display apparatus 10c according to the fourth embodiment. The structure includes an external designated information storage 130i, which is not there in the functional block diagram of the first embodiment. The following is a description of the external designated information storage 130i.

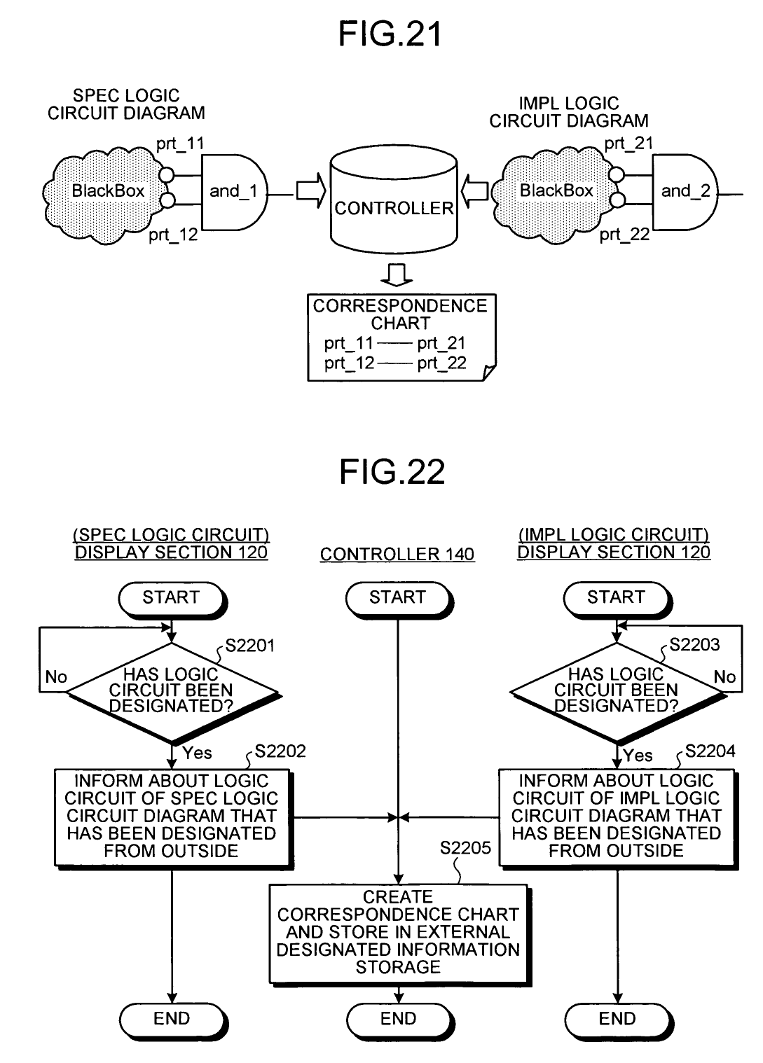

The external designated information storage 130i stores information of instances and ports corresponding to the Spec logic circuit and the Impl logic circuit, designated by the user. An example of a display of the Spec logic circuit and Impl logic circuit associated based on the external designated information stored in the external designated information storage 130i is described below with reference to FIG. 21. FIG. 21 is the example of the display of the Spec logic circuit and the Impl logic circuit associated based on the external designated information stored in the external designated information storage 130i.

As shown in FIG. 21, when there is a black box in the Spec logic circuit diagram and the Impl logic circuit diagram, the circuit diagram display apparatus 10c cannot associate the Spec logic circuit diagram and the Impl logic circuit diagram from the identification information, the structural information, and the logical equivalence information. In such a case, the user can designate ports prt_11, prt_12 of the Spec logic circuit diagram and ports prt_21 and prt_22 of the Impl logic circuit diagram as corresponding locations. The display controller 140b creates a correspondence chart from information related to the ports designated, and stores the correspondence chart in the external designated information storage 130i.

The external designation procedure for storing the external designated information in the external designated information storage 130i is described below with reference to the flowchart shown in FIG. 22. The external designation procedure is performed when a user designates a logic circuit corresponding to the Spec logic circuit diagram and the Impl logic circuit diagram.

As shown in FIG. 22, the (Spec logic circuit) display section 120 waits till the user designates the logic circuit (step S2201). The user designates from outside a logic circuit in the Spec logic circuit diagram on the screen by clicking with the mouse. If the user designates the logic circuit (Yes at step S2201), the display section 120 informs the display controller 140b that the logic circuit has been designated from outside (step S2202).

On the other hand, the (Impl logic circuit) display section 120 waits till the user designates the logic circuit (step S2203). The user designates from outside a logic circuit in the Impl logic circuit diagram on the screen by clicking with the mouse. If the user designates the logic circuit (Yes at step S2203), the display section 120 informs the display controller 140b that the logic circuit has been designated from outside (step S2204). Further, the display controller 140b creates a correspondence chart of the logic circuit, and stores it in the external designated information storage 130i (step S2205).

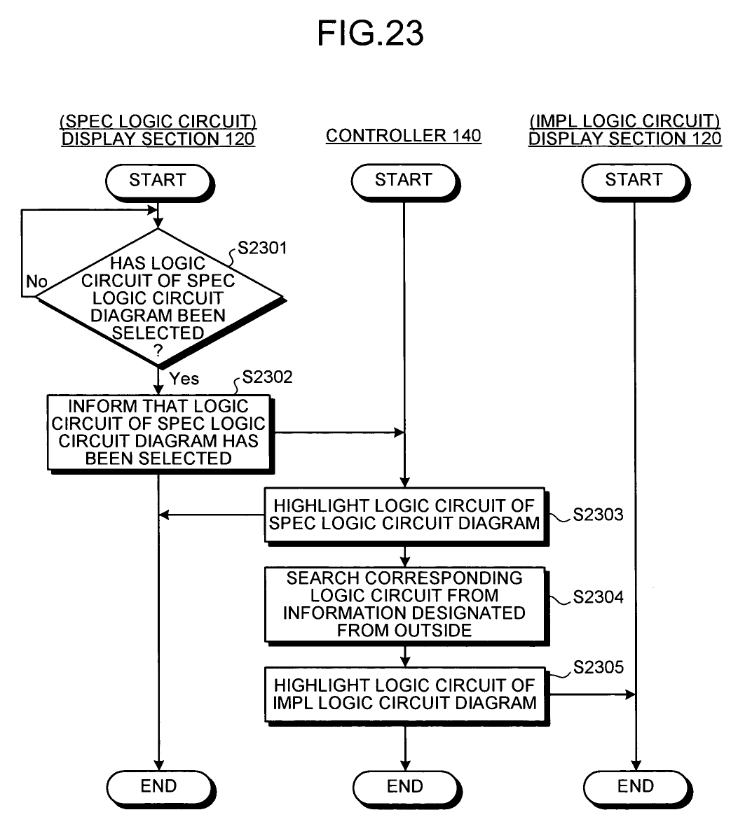

A circuit diagram display procedure executed by the circuit diagram display apparatus 10c shown in FIG. 20 is described below with reference to the flowchart shown in FIG. 23. The circuit diagram display procedure is performed when a user selects a logic circuit from the Spec logic circuits that are displayed on the display section 120.

As shown in FIG. 23, the (Spec logic circuit) display section 120 waits till the user selects the logic circuit (step S2301). The user selects a logic circuit in the Spec logic circuit diagram on the screen by clicking with the mouse.

If the user selects the logic circuit (Yes at step S2301), the display section 120 informs the display controller 140b that the logic circuit in the Spec logic circuit diagram has been selected (step S2302). The display controller 140b then highlights the logic circuit selected by the user (step S2303). Concretely, the display controller 140b highlights the logic circuit by changing the color of the display of the corresponding logic circuit. The logic circuit associating section 140d searches a logic circuit in the Impl logic circuit diagram corresponding to the logic circuit selected, based on the external designated information stored in the external designated information storage 130i (step S2303), and the display controller highlights the corresponding logic circuit in the Impl logic circuit diagram (step S2305).

Thus, according to the fourth embodiment, the logic circuit associating section 140d is made to associate the logic circuit in the Spec logic circuit diagram with the logic circuit in the Impl logic circuit diagram. Therefore, circuit diagram display apparatus 10c can display efficiently, the corresponding location of the logic circuit compared.

The fifth embodiment describes the side by side display of the plurality of circuit diagrams that are associated based on the identification information, the structural information, the logical equivalence information, and the external designated information of the logic circuits, by the circuit diagram display apparatus.

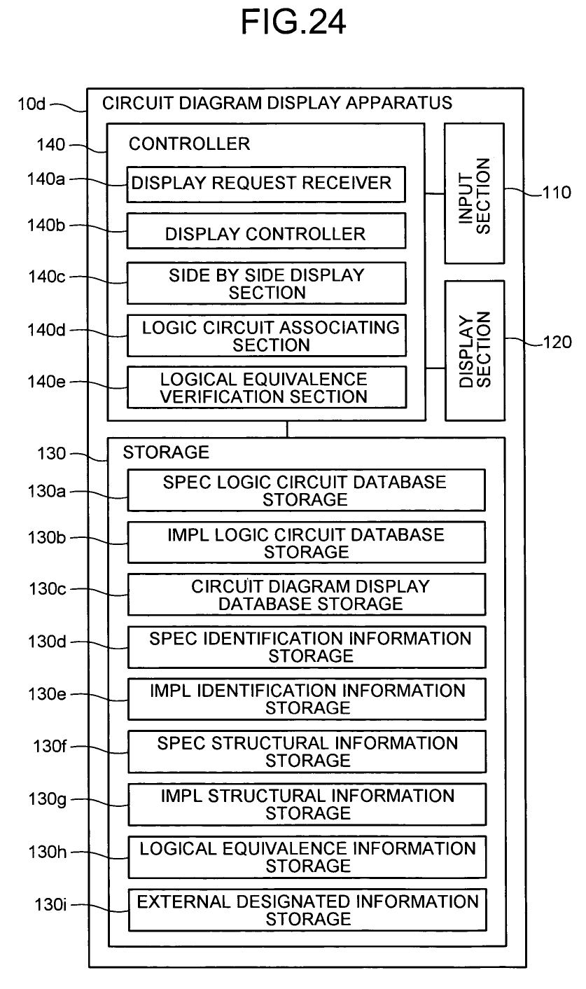

A structure of a circuit diagram display apparatus 10d according to the fifth embodiment is described below with reference to FIG. 24. FIG. 24 is a functional block diagram of the structure of the circuit diagram display apparatus 10d according to the fifth embodiment. As shown in FIG. 24, an individual structure of the circuit diagram display apparatus 10d has been described while describing the structures of the circuit diagram display apparatuses 10, 10a, 10b, and 10c according to the first, second, third, and fourth embodiments, respectively. Hence, the description of the individual structure is omitted.

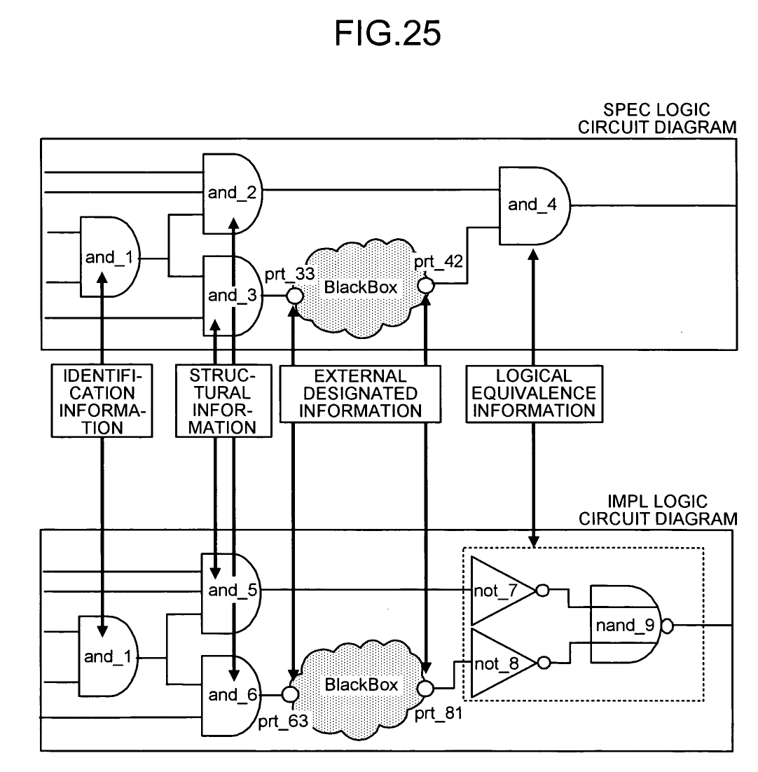

An example of a display of a plurality of logic circuits associated based on the identification information, structural information, logical equivalence information, and the external designated information by the circuit diagram display apparatus 10d shown in FIG. 24 is described below with reference to FIG. 25. FIG. 25 is the example of the display of the plurality of logic circuits associated based on the identification information, the structural information, the logical equivalence information, and the external designated information by the circuit diagram display apparatus 10d.

As shown in FIG. 25, an instance and_1 is associated with the Spec logic circuit diagram and the Impl logic circuit diagram according to the identification information, and instances and_2 and and_3 are associated with instances and_5 and and_6 according to the structural information. Moreover, ports prt_33 and prt_42 are associated with ports prt_63 and prt_81 according to the external designated information, and an instance and_4 is associated with instances not_7, not_8, and nand_9 according to the logical equivalence information.

Thus, the circuit diagram display apparatus 10d can associate the Spec logic circuit diagram and the Impl logic circuit diagram based on a combination of the identification information, the structural information, the logical equivalence information, and the external designated information, thereby enabling a link operation with high accuracy.

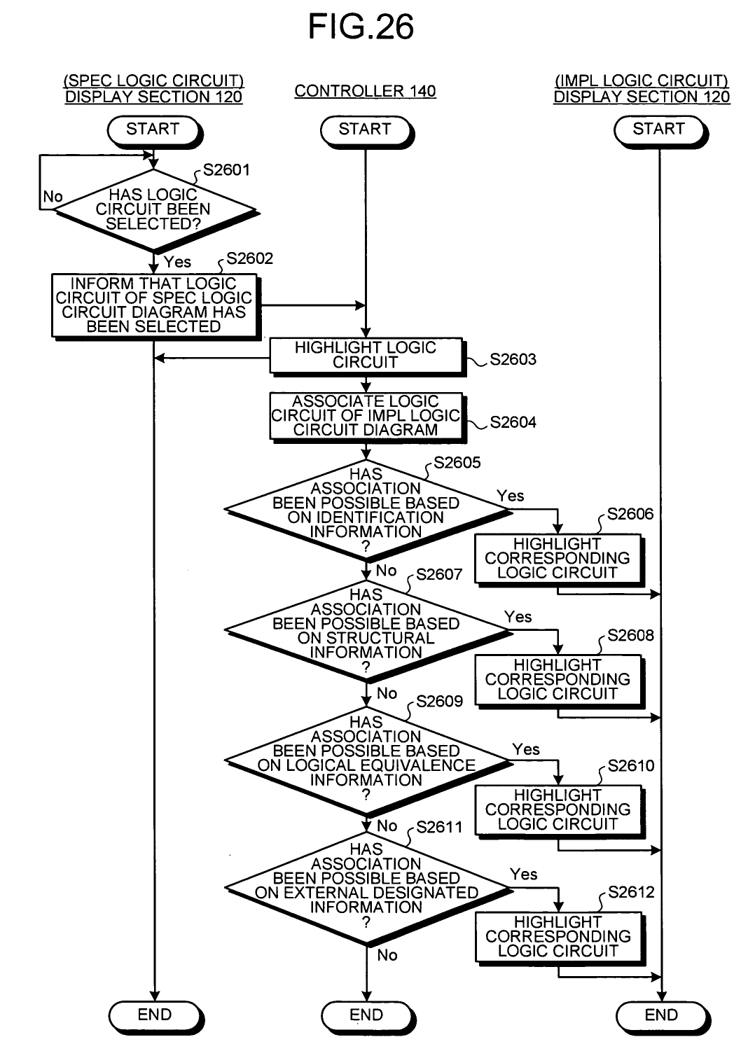

The circuit diagram display procedure executed by the circuit diagram display apparatus 10d shown in FIG. 24 is described below with reference to the flowchart shown in FIG. 26. The circuit diagram display procedure is performed when a user selects a logic circuit from the Spec logic circuits that are displayed on the display section 120.

As shown in FIG. 26, the (Spec logic circuit) display section 120 waits till the user selects the logic circuit (step S2601). The user selects a logic circuit in the Spec logic circuit diagram on the screen by clicking with the mouse.

If the user selects the logic circuit (Yes at step S2601), the display section 120 informs the display controller 140b that the logic circuit in the Spec logic circuit diagram has been selected (step S2602). The display controller 140b then highlights the logic circuit selected by the user (step S2603), and the logic circuit associating section 140d associates the logic circuit selected by the user with the logic circuit in the Impl logic circuit diagram (step S2604).

The display controller 140b verifies whether the logic circuit associating section 140d could associate the logic circuit selected with the logic circuit in the Impl logic circuit diagram based on the identification information (step S2605). If the logic circuit selected could be associated with the logic circuit in the Impl logic circuit diagram based on the identification information (Yes at step S2605), the display controller 140b highlights the corresponding logic circuit in the Impl logic circuit diagram (step S2606).

On the other hand, if the logic circuit selected could not be associated with the logic circuit in the Impl logic circuit diagram based on the identification information (No at step S2605), the display controller 140b verifies whether the logic circuit associating section 140d could associate the logic circuit selected with the logic circuit in the Impl logic circuit diagram based on the structural information (step S2607). If the logic circuit selected could be associated with the logic circuit in the Impl logic circuit diagram based on the structural information (Yes at step S2607), the display controller 140b highlights the corresponding logic circuit in the Impl logic circuit diagram (step S2608).

On the other hand, if the logic circuit selected could not be associated with the logic circuit in the Impl logic circuit diagram based on the structural information (No at step S2607), the display controller 140b verifies whether the logic circuit associating section 140d could associate the logic circuit selected by the user with the logic circuit in the Impl logic circuit diagram based on the logical equivalence information (step S2609). If the logic circuit selected could be associated with the logic circuit in the Impl logic circuit diagram based on the logical equivalence information (Yes at step S2609), the display controller 140b highlights the corresponding logic circuit in the Impl logic circuit diagram (step S2610).

On the other hand, if the logic circuit selected could not be associated with the logic circuit in the Impl logic circuit diagram based on the logical equivalence information (No at step S2609), the display controller 140b verifies whether the logic circuit associating section 140d could associate the logic circuit selected by the user with the logic circuit in the Impl logic circuit diagram based on the external designated information (step S2611). If the logic circuit selected by the user could be associated with the logic circuit in the Impl logic circuit diagram based on the external designated information (Yes at step S2611), the display controller 140b highlights the corresponding logic circuit in the Impl logic circuit diagram (step S2612). On the other hand, if the logic circuit selected could not be associated with the logic circuit in the Impl logic circuit diagram based on the external designated information (No at step S2611), the display controller 140b ends the circuit diagram display procedure.

Thus, the display controller 140b associates the Spec logic circuit diagram and the Impl logic circuit diagram based on the combination of the identification information, the structural information, the logical equivalence information, and the external designated information, and then displays the circuit diagrams. The circuit diagram display apparatus 10d can display efficiently, the corresponding location of the logic circuit compared in the logical equivalence verification. Moreover, if the Spec logic circuit diagram and the Impl logic circuit diagram cannot be associated based on the combination of the identification information, the structural information, the logical equivalence information, and the external designated information, no association is performed to avoid misrecognition.

In the circuit diagram display apparatus 10d, the Spec logic circuit diagram and the Impl logic circuit diagram are associated without setting a priority order of the identification information, the structural information, the logical equivalence information, and the external designated information. However, the present invention is not restricted to association without setting the priority order. In the circuit diagram display apparatus 10d, the priority order of the identification information, the structural information, the logical equivalence information, and the external designated information can be set, and the Spec logic circuit diagram and the Impl logic circuit diagram can be associated based on the priority order set. Moreover, a setting can also be done so that the logic circuit diagrams cannot be associated based on specific information.

Thus, according to the fifth embodiment, the logic circuit associating section 140d is made to associate a plurality of circuits based on the combination of the identification information, the structural information, the logical equivalence information, and the external designated information, thereby enabling the circuit diagram display apparatus to display efficiently, the corresponding location of the logic circuit compared.

According to one aspect of the present invention, the efficiency of operation and of debugging improves.

Moreover, there is no need for the designer to operate the plurality of circuit diagrams separately.

Furthermore, the circuit diagrams can be displayed in a format selected and switching between the display formats is possible, and each of these can be performed by a single operation.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A circuit diagram display apparatus that displays circuit areas side by side on a display screen, wherein the circuit area includes any one of a part and a whole of a plurality of circuit diagrams, the circuit diagram display apparatus comprising:
a display format changing unit that changes a display format in any one way of from a one-below-the-other format to a side-by-side format, and from the side-by-side format to the one-below-the-other format by executing a command once, when the circuit area of the circuit diagram on the display screen is displayed in any one of the one-below-the-other format and the side-by-side format; and
a display controller that performs a display control to display a target point in the circuit area, in the same position before and after the change in the display format, while the display format changing unit changes the display format on the display screen.

2. The circuit diagram display apparatus according to claim 1, wherein
the display format changing unit includes a judging unit that makes a judgment of the format in which the circuit area is to be displayed, based on an aspect ratio of each circuit diagram, when the entire circuit diagrams are to be displayed as the circuit area, and
the display format changing unit changes the display format based on the judgment made.

3. The circuit diagram display apparatus according to claim 1, wherein
the display format changing unit includes a judging unit that makes a judgment of the format in which the circuit area is to be displayed, based on an aspect ratio of a rectangular area, when a user designates the rectangular area including a part of the circuit diagrams as the circuit area to be displayed, and
the display format changing unit changes the display format based on the judgment made.

4. The circuit diagram display apparatus according to claim 3, further comprising:
a designating unit that designates the rectangular area to be displayed from among the circuit diagrams that are displayed on the display screen, and the judging unit makes the judgment based on the aspect ratio of the rectangular area designated.

5. A circuit diagram display apparatus that displays circuit areas side by side on a display screen, wherein the circuit area includes any one of a part and a whole of a plurality of circuit diagrams, the circuit diagram display apparatus comprising:
an associating unit that associates any one of a part of a circuit and an element that appears in various circuit areas in the plurality of the circuit diagrams;
a gang controller that performs gang control of any one of a part of a circuit and an element included in a second circuit area associated with any one of a part of a circuit and an element of a predetermined circuit area from among the plurality of circuit areas, while any one of the part of the circuit and the element included in the predetermined circuit area is being operated.

6. The circuit diagram display apparatus according to claim 5, further comprising:
a storage unit that stores identification information after associating the identification information with any one of each the element and each the part of the circuit in the plurality of circuit diagrams, wherein
the associating unit associates any one of the part of the circuit and the element having identification information that is identical with that appearing in the plurality of circuit diagrams, based on the identification information stored.

7. The circuit diagram display apparatus according to claim 5, further comprising:
a structural equivalence judging unit that judges an equivalence of a circuit structure, wherein
the associating unit associates the part of the circuit with an equivalent structure appearing in the plurality of circuit diagrams, based on the judgment made.

8. The circuit diagram display apparatus according to claim 5, further comprising:
a logical equivalence judging unit that judges a logical equivalence of the circuit, wherein
the associating unit associates the part of the circuit with an equivalent logic appearing in the plurality of the circuit diagrams, based on the judgment made.

9. The circuit diagram display apparatus according to claim 5, wherein the associating unit associates the part of the circuit based on an equivalent point set from outside.

10. A method for displaying circuit areas side by side on a display screen, wherein the circuit area includes any one of a part and a whole of a plurality of circuit diagrams, the method comprising:
changing a display format in any one way of from a one-below-the-other format to a side-by-side format, and from the side-by-side format to the one-below-the-other format by executing a command once, when the circuit area of the circuit diagram on the display screen is displayed in any one of the one-below-the-other format and the side-by-side format; and
performing a display control to display a target point in the circuit area, in the same position before and after the change in the display format, while the display format on the display screen is being changed.

11. A method for displaying circuit areas side by side on a display screen, wherein the circuit area includes any one of a part and a whole of a plurality of circuit diagrams, the method comprising:
associating any one of a part of a circuit and an element that appears in various circuit areas in the plurality of the circuit diagrams;
performing gang control of any one of a part of a circuit and an element included in a second circuit area associated with any one of a part of a circuit and an element of a predetermined circuit area from among the plurality of circuit areas, while any one of the part of the circuit and the element included in the predetermined circuit area is being operated.

12. A recording medium that records thereon a computer program including instructions, which when executed, make a computer execute:
changing a display format in any one way of from a one-below-the-other format to a side-by-side format, and from the side-by-side format to the one-below-the-other format by executing a command once, when the circuit area of the circuit diagram on the display screen is displayed in any one of the one-below-the-other format and the side-by-side format; and
performing a display control to display a target point in the circuit area, in the same position before and after the change in the display format, while the display format on the display screen is being changed.

13. A recording medium that records thereon a computer program including instructions, which when executed, make a computer execute:
associating any one of a part of a circuit and an element that appears in various circuit areas in the plurality of the circuit diagrams;
performing gang control of any one of a part of a circuit and an element included in a second circuit area associated with any one of a part of a circuit and an element of a predetermined circuit area from among the plurality of circuit areas, while any one of the part of the circuit and the element included in the predetermined circuit area is being operated.
